(19) United States
(12) Patent Application Publication
(10) Pub. No.: US 2003/0122258 A1
(43) Pub. Date: Jul. 3, 2003

(54) Current crowding reduction technique using slots

(76) Inventors: Sudhakar Bobba, Sunnyvale, CA (US); Tyler Thorp, Sunnyvale, CA (US)

Correspondence Address: ROSENTHAL & OSHA L.L.P., Suite 2800, 1221 McKinney, Houston, TX, 77010, US

(21) Appl. No.: 10/033,008

(22) Filed: Dec. 28, 2001

(51) Int. Cl. H01L 23/48

(52) U.S. Cl. 257/773

(57) ABSTRACT

A current crowding reduction technique that uses slots positioned between vias and a bump on a metal layer is provided. The presence of slots between the vias and the bump allows current path lengths from the vias to the bump to made substantially equal. Because the current paths have substantially equal current flow among them when the current path lengths are substantially equal, current flows from the vias to the bump in a more uniform manner. Further, a bump and vias structure that uses slots disposed in between vias and a bump is also provided. Further, a method for designing a metal layer having slots positioned in between vias and a bump is also provided.

### BACKGROUND OF THE INVENTION

A typical computer system includes at least a microprocessor and some form of memory. The microprocessor has, among other components, arithmetic, logic, and control circuitry that interpret and execute instructions necessary for the operation and use of the computer system. FIG. 1 shows a typical computer system (10) having a microprocessor (12), memory (14), integrated circuits (16) that have various functionalities, and communication paths (18), i.e., buses and wires, that are necessary for the transfer of data among the aforementioned components in the computer system (10).

An integrated circuit, such as the ones shown in FIG. 1, is electrically connected to a circuit board via a chip package. A chip package, which houses semiconductor devices in strong, thermally stable, hermetically sealed environments, provides a semiconductor device, e.g., the integrated circuit, with electrical connectivity to circuitry external to the semiconductor device. FIG. 2 shows one prior art type of chip package assembly that involves wire bond connections. The wire bonding process involves mounting a integrated circuit (30) to a substrate (32) with its inactive backside (34) down. Wires (not shown) are then bonded between an active side (36) of the integrated circuit (30) and the chip package (not shown).

FIG. 3 shows a more recently developed type of chip package assembly known as “flip-chip” packaging. In flip-chip package technology, an integrated circuit (40) is mounted onto a chip package (42), where the active side of the integrated circuit (40) is electrically interfaced to the chip package (42). Specifically, the integrated circuit (40) has bumps (44) on bond pads (not shown and also known and referred to as “landing pads”) formed on an active side (46) of the integrated circuit (40), where the bumps (44) are used as electrical and mechanical connectors. The integrated circuit (40) is inverted and bonded to chip package (42) by means of the bumps (44). Various materials, such as conductive polymers and metals (referred to as “solder bumps”), are commonly used to form the bumps (44) on the integrated circuit (40).

As discussed above with reference to FIG. 3, the bumps (44) on the integrated circuit (40) serve as electrical pathways between the components within the integrated circuit (40) and the chip package (42). Within the integrated circuit (40) itself, an arrangement of conductive pathways and metal layers form a means by which elements in the integrated circuit (40) operatively connect to the bumps (44) on the outside of the integrated circuit (40). To this end, FIG. 4a shows a side view of the integrated circuit (40). The integrated circuit (40) has several metal layers, M1-M8, surrounded by some dielectric material (48), e.g., silicon dioxide. The metal layers, M1-M8, are connected to each other by conductive pathways (50) known as “vias.” Vias (50) are essentially holes within the dielectric material (48) that have been doped with metal ions.

Circuitry (not shown) embedded on a substrate of the integrated circuit (40) transmit and receive signals via the metal layers, M1-M8, and the vias (50).

Signals that need to be transmitted/received to/from components external to the integrated circuit (40) are propagated through the metal layers, M1-M8, and vias (50) to the top metal layer, M8. The top metal layer, M8, then transmits/receives signals and power to/from the bumps (44) located on the active side of the integrated circuit (40).

FIG. 4b shows a top view of the integrated circuit (40) shown in FIG. 4a. The top metal layer, M8, as shown in FIG. 4b, has a number of parallel regions. These parallel regions alternate between regions connected to V_{DD} and regions connected to V_{SS}. Such a configuration helps reduce electromagnetic interference. The top metal layer, M8, is configured such that it is orthogonal with the metal layer below, M7, as shown in FIG. 4b. Further, bumps (44) on the top metal layer, M8, are arranged in a non-uniform fashion with some areas of the top metal layer, M8, having larger numbers of bumps (44) than other areas.

### SUMMARY OF INVENTION

According to one aspect of the present invention, a bump and vias structure comprises a metal layer, a plurality of vias connecting the metal layer to another metal layer, a bump mounted on the metal layer, and a first slot formed in the metal layer between the vias and the bump.

According to another aspect, an integrated circuit comprises a metal layer, a plurality of vias connecting the metal layer to another metal layer, a bump mounted on the metal layer, and a first slot formed in the metal layer between the vias and the bump.

According to another aspect, a method for reducing current crowding in a bump and vias structure comprises determining a length of a first current path between a first via and a bump, determining a length of a second current path between a second vias and the bump, and disposing a slot along one of the first and second current paths depending on the first and second current path lengths.

Other aspects and advantages of the invention will be apparent from the following description and the appended claims.

### BRIEF DESCRIPTION OF DRAWINGS

FIG. 1 shows a typical computer system.

FIG. 2 shows a typical chip package assembly.

FIG. 3 shows a typical flip-chip package assembly.

FIG. 4a shows a view of a typical integrated circuit.

FIG. 4b shows another view of the typical integrated circuit shown in FIG. 4a.

FIG. 4c shows an enlarged view of a bump and vias structure in accordance with the examples shown in FIGS. 4a and 4b.

FIG. 5a shows a top view of a bump and vias structure in accordance with an embodiment of the present invention.

FIG. 5b shows a top view of a bump and vias structure in accordance with the embodiment shown in FIG. 5a.

FIG. 6a shows a top view of a bump and vias structure in accordance with another embodiment of the present invention.

FIG. 6b shows a top view of a bump and vias structure in accordance with the embodiment shown in FIG. 6a.

FIG. 7a shows a top view of a bump and vias structure in accordance with another embodiment of the present invention.

FIG. 7b shows a top view of a bump and vias structure in accordance with the embodiment shown in FIG. 7a.

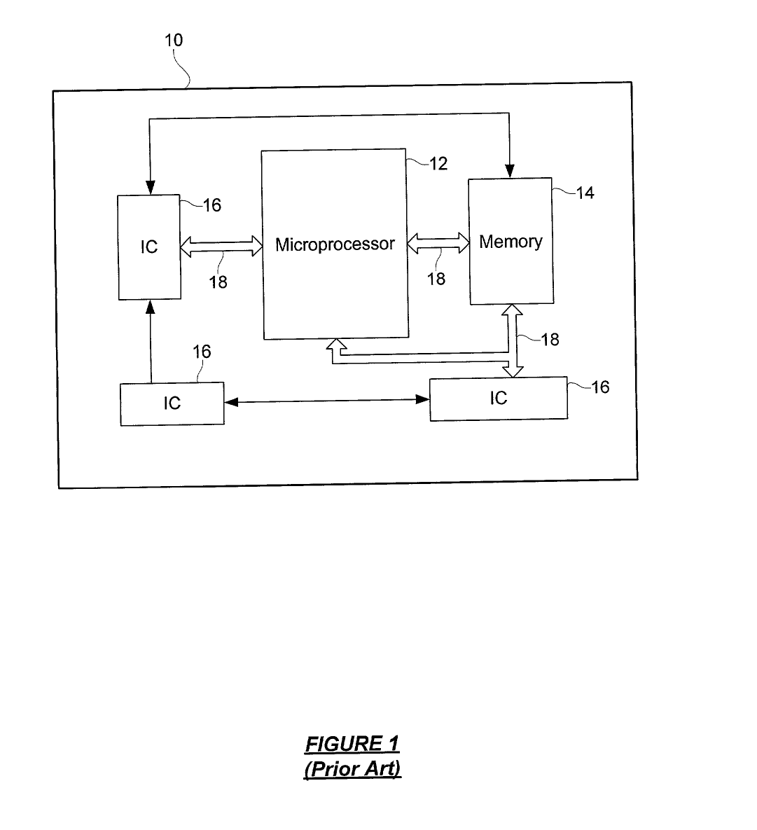

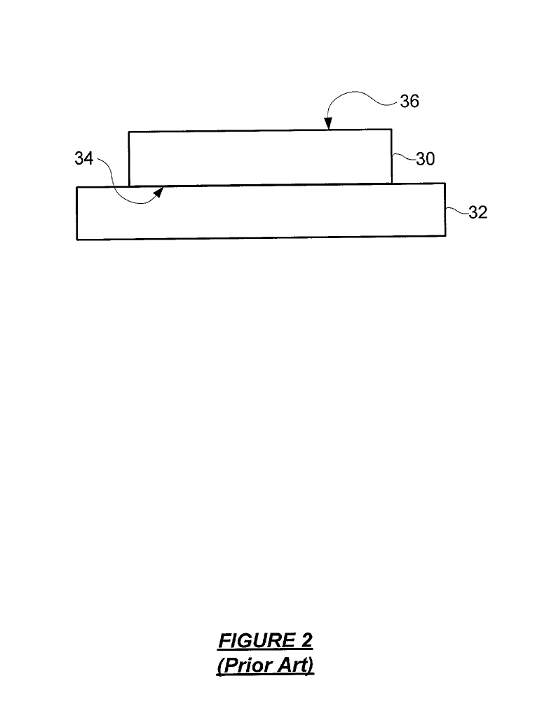

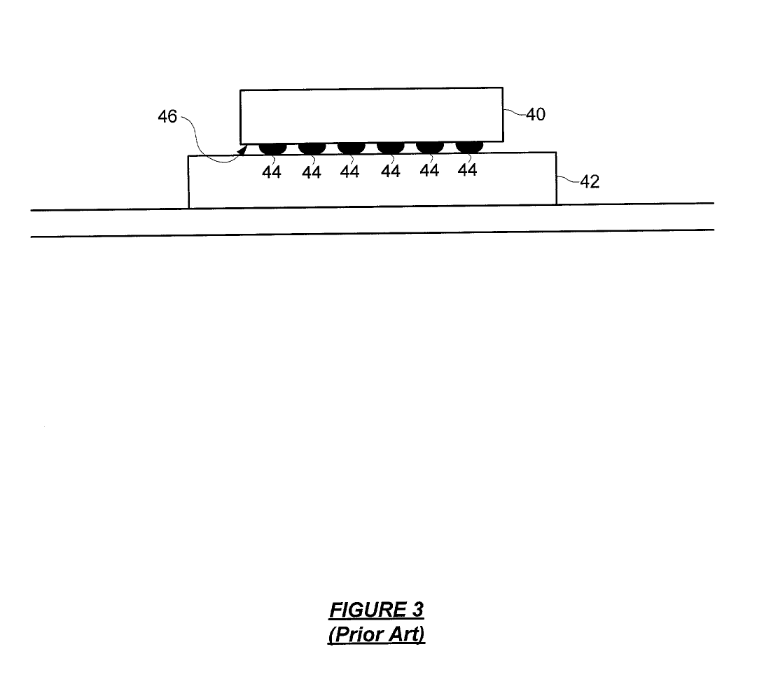

### DETAILED DESCRIPTION

Detailed exemplary embodiments of the present invention will now be described with reference to the accompanying figures. Embodiments of the present invention are related to a bump and vias structure that allows for increased uniformity of current distribution around the bump. Embodiments of the present invention further relate to a method for reducing current crowding by more uniformly distributing current to and from a bump.

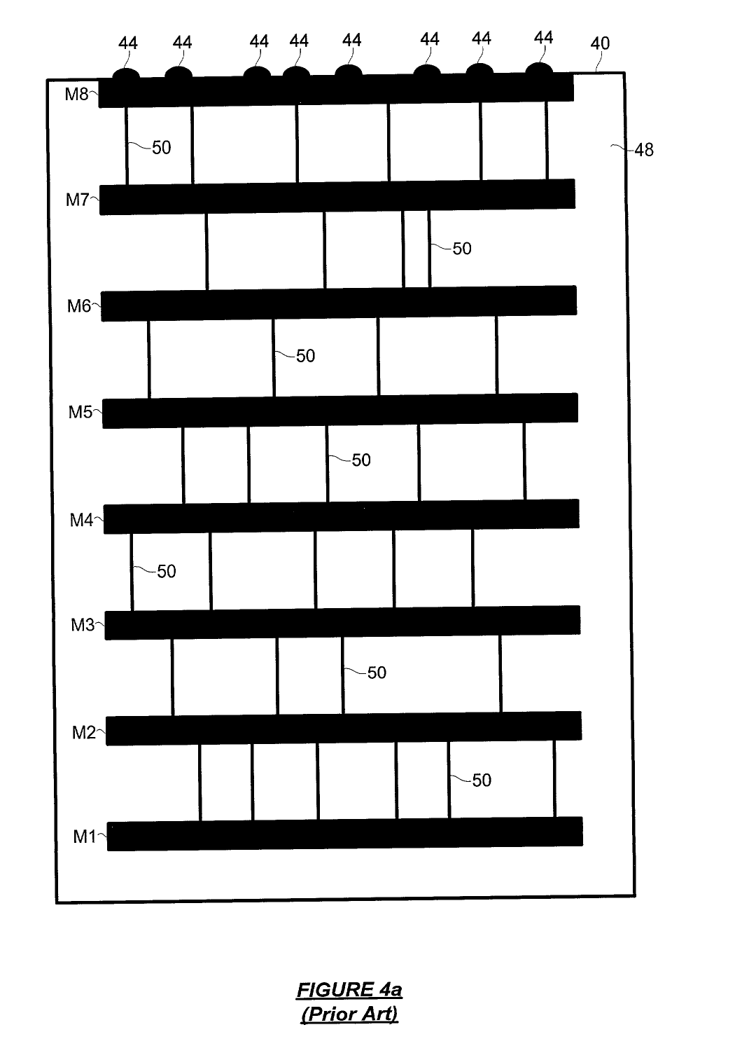

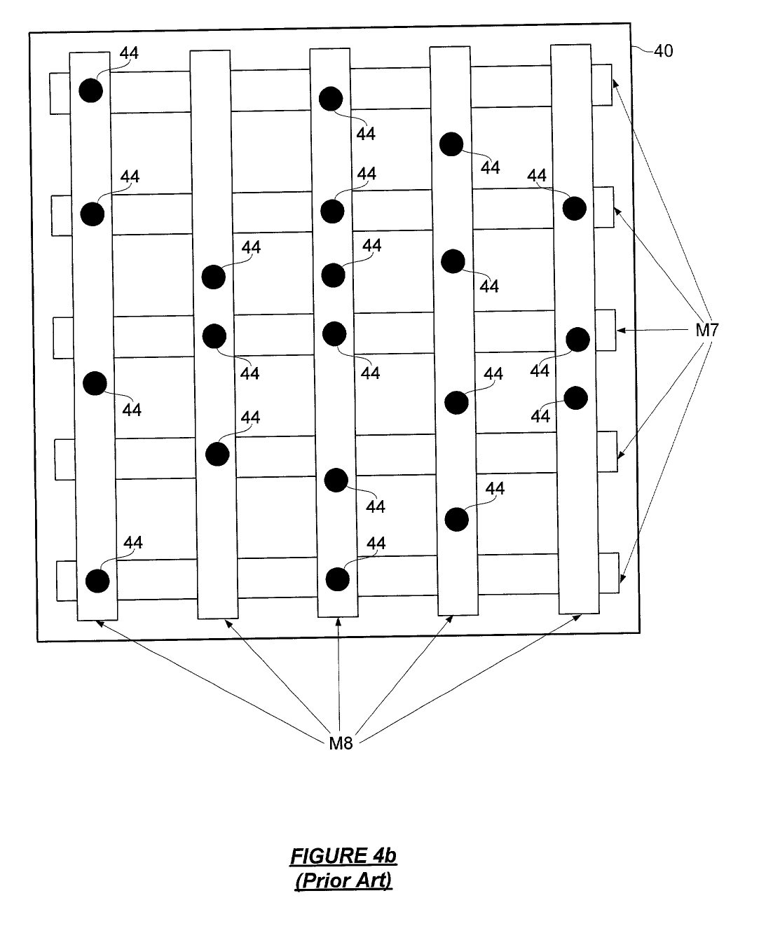

FIG. 4c shows an enlarged section of the integrated circuit (40) shown in FIG. 4b. Although a section of an integrated circuit is used for this example, the invention is equally applicable to all bump and vias structures in an integrated circuit. The bump (44) shown in FIG. 4c is connected to the top metal layer, M8. Vias (50) are used to connect the bump (44), the top metal layer, M8, and the one or more metal layers below (shown here as layer M7).

Vias (50) provide current paths across the junction between the bump (44) and the top metal layer, M8. The part of the top metal layer, M8, that makes contact with the bump is known as its “landing pad” (52). Thus, current is carried to or from the bump (44) from or to the vias (50) by layer M8 and the landing pad (52). Arrows indicating the flow of current from the bump (44) to the vias (50) are shown for illustration purposes in FIG. 4c. Although the vias (50) facilitate current flow, because the vias (50) are positioned laterally across the layer M8, and the bump (44) is circular, there is non-uniform current density at the junction between the bump (44) and the top metal layer, M8. This non-uniform current density, resulting from the differences in current path length from the vias (50) to the bump (44), is known as “current crowding.” In this current crowding phenomenon, there is high current density at a region (54) of the bump (44) that is in closest proximity to the vias (50), and there is lower current density in the rest of the junction between the bump (44) and the landing pad (52). For example, in FIG. 4c, it can be seen that the shortest current path length is along arrow (53a), resulting in current crowding in region (54). A lower concentration of current flow occurs along arrows (53b), and an even lower concentration of current flow occurs along arrows (53c). Those skilled in the art will note that in FIG. 4c, the relative thicknesses among arrows from the vias (50) to the bump (44) are indicative of the relative current densities of the various current flow paths. For example, arrow (53a) has a higher current density than arrows (53c), and thus arrow (53a) is thicker than arrows (53c).

Current crowding is typically an undesirable effect because prolonged exposure to current crowding may cause, among other things, performance degradation, power distribution deficiencies, signal delay, and damage to the junction between the bump (44) and the landing pad (52). In some cases, damage caused by electro-migration may actually result in detachment of the bump.

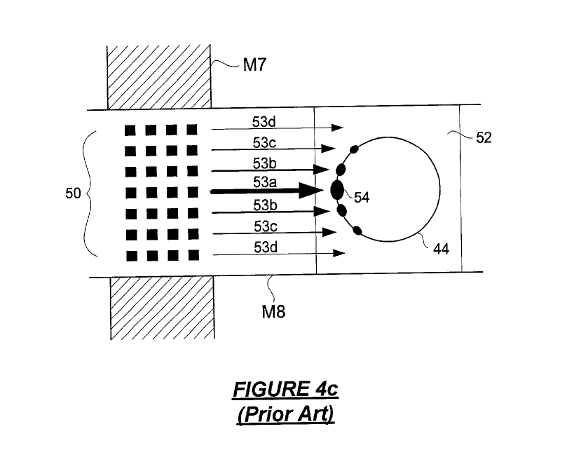

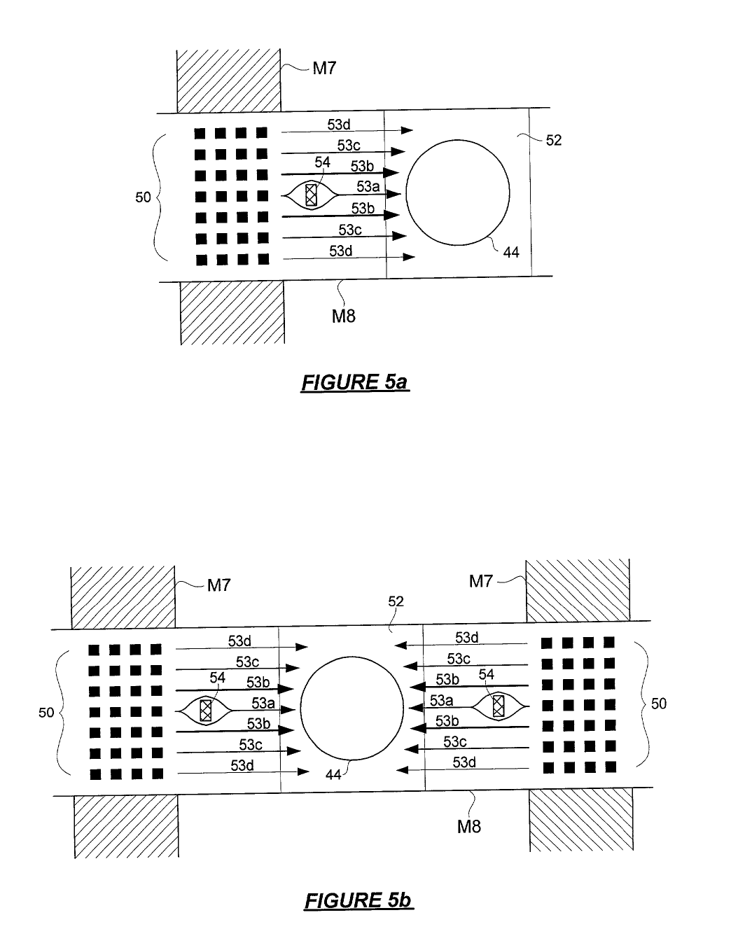

FIG. 5a shows a top view of a bump and vias structure in accordance with an embodiment of the invention. Like elements with respect to prior art FIG. 4c are denoted by like reference numerals for consistency. In this embodiment, a slot (54) has been formed in a central region of the top layer M8 between the vias (50) and the bump (44). Because current cannot flow across slot (54), the effective current path length from the vias (50) in a central region of layer M8 to the bump (44) is increased by the distance necessary for the current to flow around the slot (54). Thus, it can be seen that the current flowing along arrow (53a) is reduced relative to the current flowing along the same path without the slot as shown in FIG. 4c. Accordingly, current crowding at bump (44) is significantly reduced.

FIG. 5b shows a top view of a bump and vias structure in accordance with the embodiment shown in FIG. 5a. In FIG. 5b, current distribution to the bump (44) is shown where vias and slots are disposed on the metal layer, M8, on both sides of the bump (44). Current to the bump flows from the vias (50) as shown by arrows (53a, 53b, 53c, 53d), and because the presence of slots between the vias (50) and the bump (40) forces current paths that typically would have high current densities (due to shorter current path lengths from via to bump) to become longer, the current path lengths from the vias (50) to the bump (44) are all substantially the same, and also, the current flow density along the current paths (53a, 53b, 53c, 53d) are all substantially the same from via to bump. Thus, as shown in FIG. 5b, the bump (44) experiences substantially uniform current distribution from the vias, effectively reducing current crowding at the bump (44).

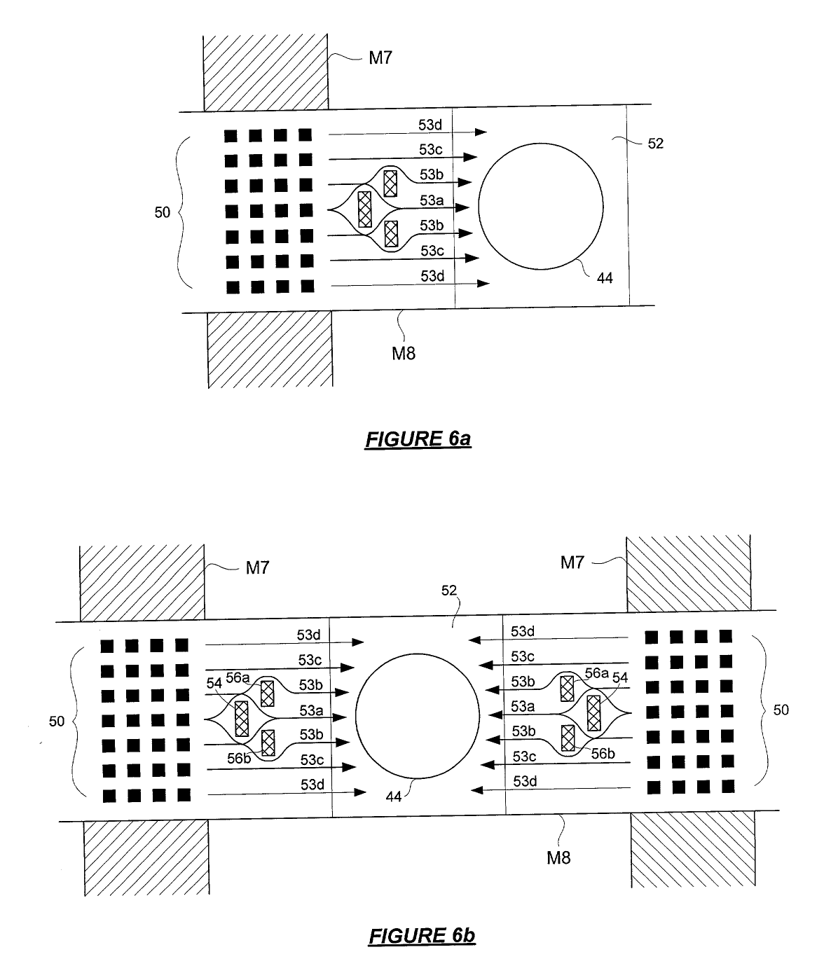

Turning now to FIG. 6a, another embodiment of the invention is shown wherein uniformity of current distribution is further enhanced. In this embodiment, in addition to slot (54), two additional slots (56a, 56b) are disposed between slot (54) and bump (44) along a lateral line of metal layer, M8. An aperture between slots (56a, 56b) may be centered with respect to slot (54). Current that flows around slot (54) is permitted to flow through the aperture between slots (56a, 56b) along arrow (53a). However, current that bypasses slot (54), but runs close thereto, is forced to flow around slots (56a, 56b) along arrow (53b). Current along the outside of the layer M8 is not affected, e.g., arrow (53c). Accordingly, greater uniformity of current flow at bump (44) is achieved than in cases where slots are not used.

FIG. 6b shows a top view of a bump and vias structure in accordance with the embodiment shown in FIG. 6a. In FIG. 6b, current distribution to the bump (44) is shown where vias and slots are disposed on the metal layer, M8, on both sides of the bump (44). Current to the bump flows from the vias (50) as shown by arrows (53a, 53b, 53c, 53d), and because the presence of slots between the vias (50) and the bump (40) forces current paths that typically would have high current densities (due to shorter current path lengths from via to bump) to become longer, the current path lengths from the vias (50) to the bump (44) are all substantially the same, and also, the current flow density along the current paths (53a, 53b, 53c, 53d) are all substantially the same from via to bump. Thus, as shown in FIG. 6b, the bump (44) experiences substantially uniform current distribution from the vias, effectively reducing current crowding at the bump (44).

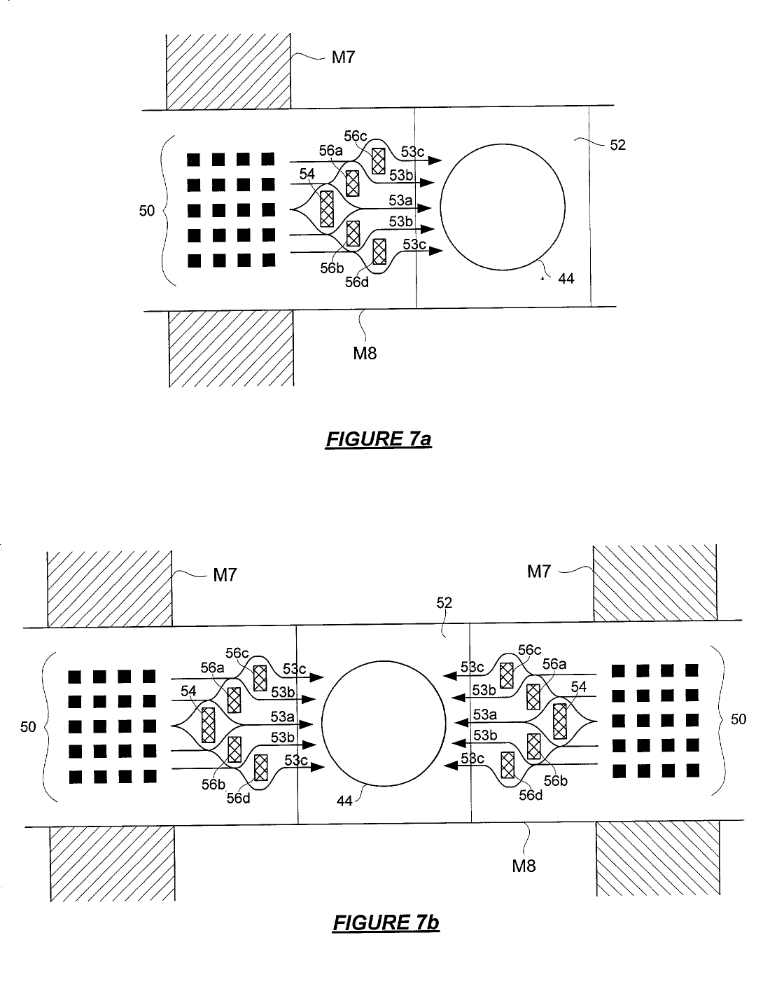

Turning now to FIG. 7a, another embodiment of the invention is shown wherein uniformity of current distribution is further enhanced. In this embodiment, in addition to slots (54, 56a, 56b), additional slots (56c, 56d) are disposed between slot (54) and bump (44) along a lateral line of metal layer, M8. In addition to current flow through the aperture between slots (56a) and (56b) along arrow (53a), current also flows through apertures between slots (56a) and (56c) and between slots (56b) and (56d) along arrows (53b). However, current that bypasses slots (56a) and (56b), but runs close thereto, may flow around slots (56c) and (56d) along arrows (53c). Accordingly, an even greater uniformity of current flow at bump (44) is achieved.

FIG. 7b shows a top view of a bump and vias structure in accordance with the embodiment shown in FIG. 7a. In FIG. 7b, current distribution to the bump (44) is shown where vias and slots are disposed on the metal layer, M8, on both sides of the bump (44). Current to the bump flows from the vias (50) as shown by arrows (53a, 53b, 53c), and because the presence of slots between the vias (50) and the bump (40) forces current paths that typically would have high current densities (due to shorter current path lengths from via to bump) to become longer, the current path lengths from the vias (50) to the bump (44) are all substantially the same, and also, the current flow density along the current paths (53a, 53b, 53c) are all substantially the same from via to bump. Thus, as shown in FIG. 7b, the bump (44) experiences substantially uniform current distribution from the vias, effectively reducing current crowding at the bump (44).

Although exemplary arrangements of slots are shown in the examples above to illustrate the invention, the skilled artisan will appreciate that any location, number, combination of slots, and/or dimensions of the slots may be used as appropriate, depending upon the physical arrangement of the vias, the bump, and the current path lengths therebetween. Moreover, considering for example the embodiment shown in FIG. 6a, additional slots may be formed in layer M8, like slots (56a) and (56b), but centered on each of slots (56a) and (56b) to further regulate current density.

The slots of the invention may be formed by preventing formation of conductive material at the desired locations, or by removal of material by etching or the like. In addition, the slots may be formed by removal of conductive material and insertion of a current impeding or dielectric material. Optionally, the slots may not completely prevent current flow thereacross, but may simply reduce current flow in a manner to achieve the desired degree of current uniformity at a bump.

The invention further relates to a method of increasing uniformity of current flow in a bump and vias structure. In accordance with the embodiments of FIGS. 5a through 7b, various path lengths between the vias (50) and the bump (44) are determined based upon the geometry of the vias and the bump. Slots are then selectively interposed between the vias and the bump to reduce current crowding at the bump.

Although, in the exemplary embodiments above, current is shown as flowing from the vias to the bump, the invention is equally applicable for situations where current flows from the bump to the vias.

While various embodiments of the invention have been shown and described, the invention is not limited to the specific embodiments disclosed. Rather, the skilled artisan will appreciate that various modifications and additions to the invention are possible and are within the scope of the invention. Accordingly, the invention shall be limited only by the scope of the appended claims.

What is claimed is:

1. A bump and vias structure, comprising:
a metal layer;
a plurality of vias connecting the metal layer to another metal layer;
a bump mounted on the metal layer; and
a first slot formed in the metal layer between the vias and the bump.

2. The bump and vias structure of claim 1, wherein the bump is mounted on the metal layer via a landing pad.

3. The bump and vias structure of claim 1, further comprising second and third slots disposed between the first slot and the bump.

4. The bump and vias structure of claim 3, wherein the second and third slots are displaced laterally along the metal layer and form an aperture therebetween that is centered with respect to the first slot.

5. The bump and vias structure of claim 1, wherein the first slot comprises a section of the metal layer that is evacuated of conductive material.

6. The bump and vias structure of claim 1, wherein the first slot comprises a current-resistant material.

7. The bump and vias structure of claim 1, wherein the first slot comprises a dielectric material.

8. An integrated circuit, comprising:
a metal layer;
a plurality of vias connecting the metal layer to another metal layer;
a bump mounted on the metal layer; and
a first slot formed in the metal layer between the vias and the bump.

9. The integrated circuit of claim 8, wherein the bump is mounted on the metal layer via a landing pad.

10. The integrated circuit of claim 8, further comprising second and third slots disposed between the first slot and the bump.

11. The integrated circuit of claim 10, wherein the second and third slots are displaced laterally along the metal layer and form an aperture therebetween that is centered with respect to the first slot.

12. The integrated circuit of claim 8, wherein the first slot comprises a section of the metal layer that is evacuated of conductive material.

13. The integrated circuit of claim 8, wherein the first slot comprises a current-resistant material.

14. The integrated circuit of claim 8, wherein the first slot comprises a dielectric material.

15. A method for reducing current crowding in a bump and vias structure, comprising:
determining a length of a first current path between a first via and a bump;
determining a length of a second current path between a second vias and the bump; and
disposing a slot along one of the first and second current paths depending on the first and second current path lengths.

16. The method of claim 15, wherein disposing the slot is dependent on whether the first current path length is longer than the second current path length.

17. The method of claim 16, wherein if the first current path length is longer than the second current path length, the slot is disposed along the second current path.

18. The method of claim 15, further comprising disposing at least one additional slot between the first slot and the bump.
